(19) United States
(12) Patent Application Publication
(10) Pub. No.: US 2005/0220183 A1
(43) Pub. Date: Oct. 6, 2005

(54) APPARATUS AND METHOD FOR IMPROVING QUALITY OF RECEIVED SIGNAL

(76) Inventor: Chao-Hsin LU, Tao-Yuan Hsien (TW)

Correspondence Address: NORTH AMERICA INTERNATIONAL PATENT OFFICE (NAIPC), P.O. BOX 506, MERRIFIELD, VA, 22116, US

(21) Appl. No.: 10/907,439

(22) Filed: Mar. 31, 2005

(30) Foreign Application Priority Data
Apr. 5, 2004 (TW) 093109378

(51) Int. Cl. H03K 5/159

(52) U.S. Cl. 375/229

(57) ABSTRACT

An equalizer having an input end and an output end comprises: a first circuit, coupled between the input end and the output end, having a first gain; and a second circuit, coupled between the input end and the output end, having a second gain; wherein a frequency response of the equalizer corresponds to the first gain and the second gain.

### BACKGROUND OF INVENTION

1. Field of the Invention

The present invention relates to an equalizer, and more particularly, to an equalizer for reducing cable response.

2. Description of the Prior Art

In signal transmission systems, channel attenuation and inter-symbol interference (ISI) generally get worse as the channel becomes longer. As a result, the signal quality is deteriorated. Therefore, an equalizer is typically employed in a signal receiver to equalize the received signal in order to compensate signal attenuation and to eliminate the ISI problem.

FIG. 1 depicts an equivalent circuit diagram of a conventional equalizer 100. In FIG. 1, for convenient analysis, it is assumed that the capacitance of a capacitor 110 is C/2; the resistance of a resistor 120 is 2R; the parasitic resistance of the current source 102 and current source 104 are both r; and the conductance of the MOS 106 and MOS 108 are both gm. Accordingly, the gain of the equalizer 100 can be presented as follows:

$$\frac{Vout}{Vin} = \frac{Iop - Ion}{Vip - Vin} \times Rl = \frac{gm ( 1 + s ( R // r ) C )}{( 1 + gm ( R // r ) ) + s ( R // r ) C} \times Rl \qquad ( 1 )$$

From formula (1), the pole and the zero of the equalizer 100 can be derived as follows:

$$\begin{matrix}pole = - \frac{1 + gm ( R // r )}{( R // r ) C} {⟶}^{r ⪢ R} - \frac{1 + gmR}{RC} & ( 2 ) \\ zero = - \frac{1}{( R // r ) C} {⟶}^{r ⪢ R} - \frac{1}{RC} & ( 3 )\end{matrix}$$

FIG. 2 depicts a simplified frequency response of the equalizer 100. In general, the equalizing performance of the equalizer 100 depends on an effective bandwidth BW, i.e., the bandwidth between the pole and the zero.

However, as can be inferred from the formula (2) and formula (3), both the zero and the pole of the equalizer 100 shift to the left while the capacitance of the capacitor 110 or the resistance of the resistor 120 increases. In contrary, both the zero and the pole of the equalizer 100 shift to the right if the capacitance of the capacitor 110 or the resistance of the resistor 120 decreases. In other words, it is difficult to adjust the effective bandwidth BW, the frequency difference between the pole and the zero, of the conventional equalizer 100 by adjusting the capacitor 110 or resistor 120. The performance of the conventional equalizer is accordingly limited.

### SUMMARY OF INVENTION

It is therefore one of the objectives of the claimed invention to provide an equalizer with improved effective bandwidth.

It is therefore one of the objectives of the present invention is to provide a signal receiver to improve the quality of the received signal.

According to a preferred embodiment of the present invention, an equalizer having an input end and an output end comprises: a first circuit, coupled between the input end and the output end, having a first gain; and a second circuit, coupled between the input end and the output end, having a second gain; wherein a frequency response of the equalizer corresponds to the first gain and the second gain.

According to a preferred embodiment of the present invention, a signal receiver comprises an equalizer and a control circuit is disclosed. The equalizer having an input end and an output end comprises: a first circuit, coupled between the input end and the output end, having a first gain; and a second circuit, coupled between the input end and the output end, having a second gain. The control circuit is coupled to the equalizer, the control circuit for generating a control signal according to a channel response for adjusting a frequency response of the equalizer.

Additionally, a signal equalizing method is disclosed comprising: receiving a signal; and compensating the received signal according to a gain; wherein the gain corresponds to a first gain and a second gain, and a frequency response of the gain comprises a pole corresponding to the first gain and a zero corresponding to the second gain.

These and other objectives of the present invention will no doubt become obvious to those of ordinary skill in the art after reading the following detailed description of the preferred embodiment that is illustrated in the various figures and drawings.

### BRIEF DESCRIPTION OF DRAWINGS

FIG. 1 is an equivalent circuit diagram of a conventional equalizer.

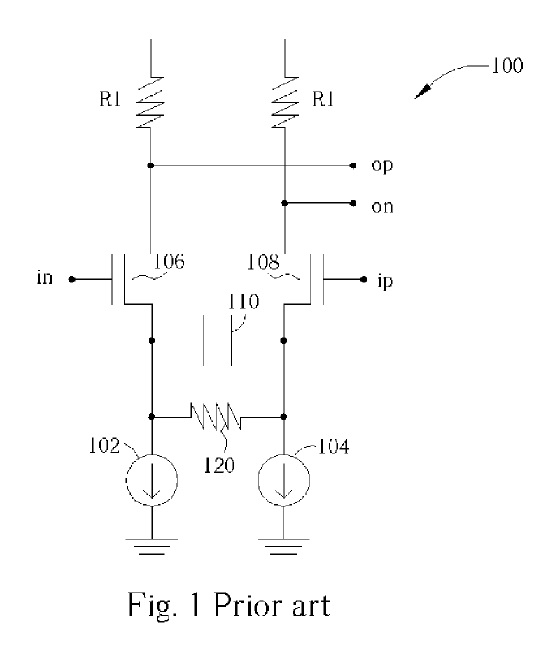

FIG. 2 is a simplified frequency response of the conventional equalizer of FIG. 1.

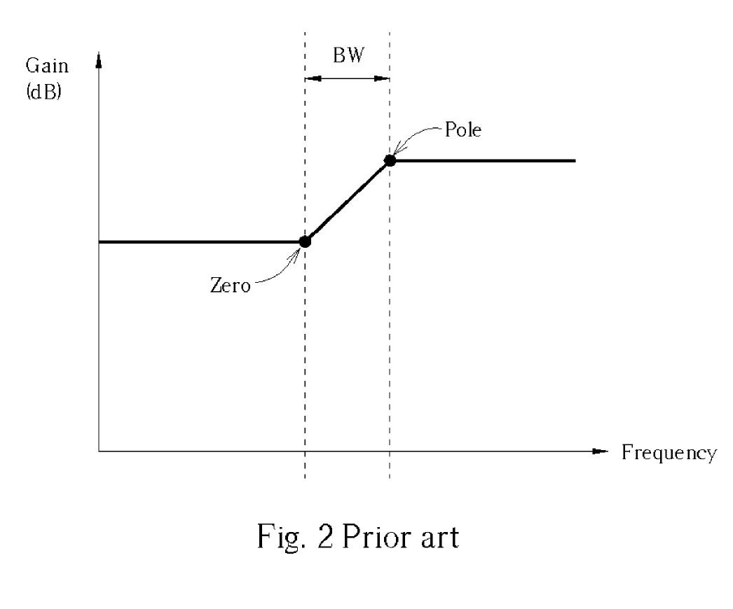

FIG. 3 is a schematic diagram of an equalizer in accordance with the present invention.

FIG. 4 is an equivalent circuit diagram of the equalizer of FIG. 3.

FIG. 5 is a simplified frequency response of the equalizer of FIG. 3.

### DETAILED DESCRIPTION

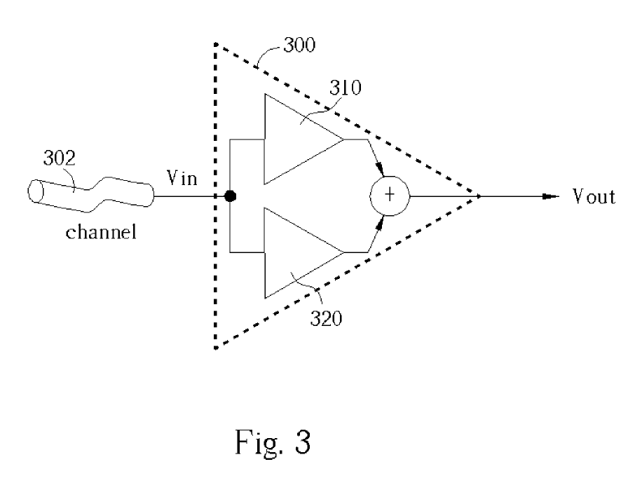

Please refer to FIG. 3, which depicts a schematic diagram of an equalizer 300 in accordance with the present invention. The equalizer 300 is used for compensating channel attenuation of a received signal Vin transmitted through a channel 302, and for reducing the ISI of the received signal Vin. The channel 302 can be various means of connection, such as USB, 1394, RS232, or the like. The equalizer 300 equalizes the received signal Vin to output a signal Vout. In a signal-receiving device, a clock-data recovery device is commonly configured following the equalizer 300 to recover the clock of the equalized signal.

The equalizer 300 comprises a first amplifying circuit 310 having an input terminal, which is coupled to the received signal Vin, and an output terminal; and a second amplifying circuit 320 having an input terminal coupled to the received signal Vin and an output terminal coupled to the output terminal of the first amplifying circuit 310. In the present invention, the signal gain of the equalizer 300 is the sum of the gain of the first amplifying circuit 310 and the gain of the second amplifying circuit 320. In a preferred embodiment, the first amplifying circuit 310 can be a differentiator and the second amplifying circuit 320 can be implemented with an attenuator.

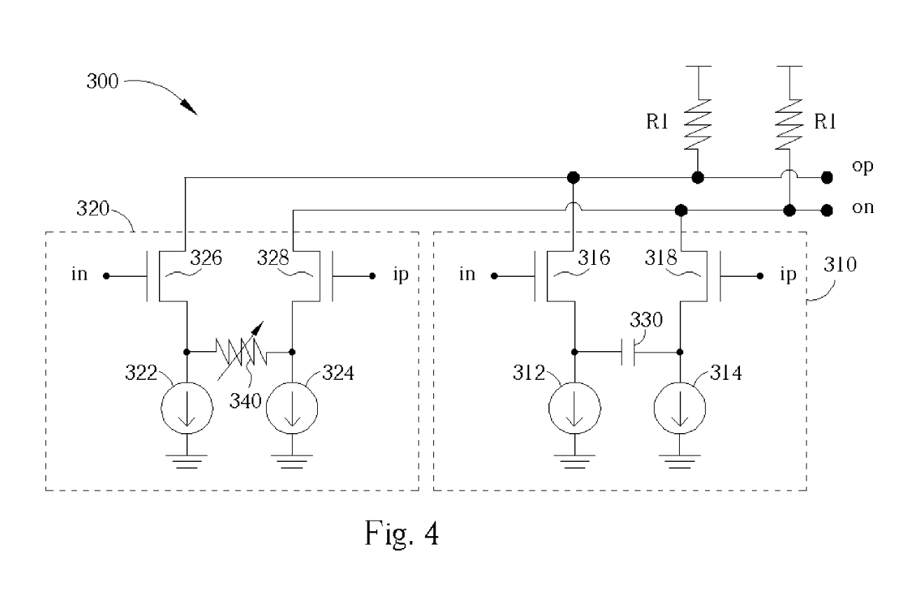

FIG. 4 depicts an equivalent circuit diagram of the equalizer 300. Similarly, for convenient analysis, the capacitance of the capacitor 330 is herein assumed to be C/2; the resistance of the resistor 340 is assumed to be 2R; the parasitic capacitance of the equivalent current sources 312 and 314 are both assumed to be r1; the conductance between the MOS 316 and MOS 318 is assumed to be gm1; the parasitic resistance of the equivalent current sources 322 and 324 are both assumed to be r2; and the conductance between the MOS 326 and MOS 328 is assumed to be gm2. The gain of the equalizer 300 is analyzed as follows:

$$\frac{Vout}{Vin} = \frac{Iop - Ion}{Vip - Vin} \times Rl = [ \frac{1}{1 + gm2 ( R // r2 )} + \frac{gm1 ( 1 + sr1C )}{( 1 + gm1r1 ) + sr1C} ] \times Rl \qquad ( 4 )$$

In practical implementations, the resistance of the resistor 340 is much smaller than r2, i.e., r2>>R, so that formula (4) can be modified as follows:

$$\frac{Vout}{Vin} \approx \frac{Rl}{1 + gm2R} + [ \frac{gm1 ( 1 + sr1C )}{( 1 + gm1r1 ) + sr1C} ] \times Rl \qquad ( 5 )$$

Wherein the item

$$[ \frac{gm1 ( 1 + sr1C )}{( 1 + gm1r1 ) + sr1C} ] \times Rl$$
represents a first gain A1 corresponding to the first amplifying circuit 310 and another item

$$\frac{Rl}{1 + gm2R}$$
represents a second gain A2 corresponding to the second amplifying circuit 320.

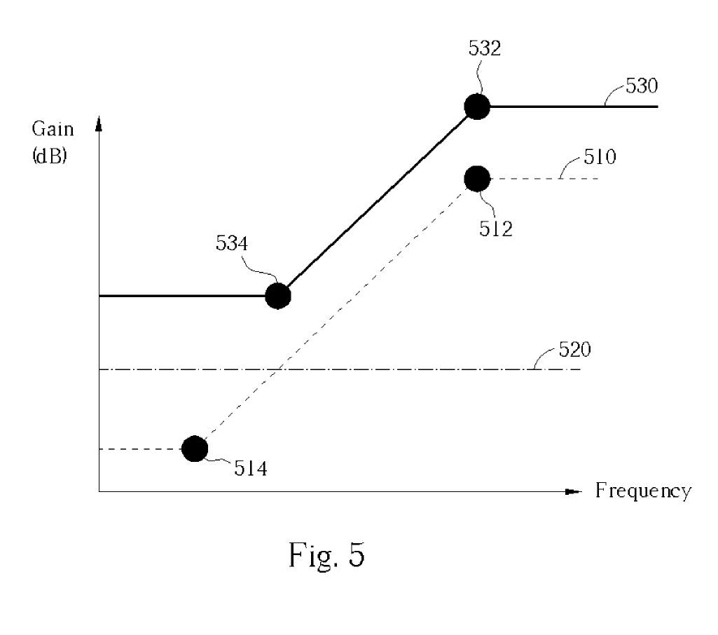

Please refer to FIG. 5, which depicts a simplified frequency response of the equalizer 300. In FIG. 5, a response function 510 corresponds to the frequency response of the first amplifying circuit 310 while another response function 520 corresponds to the frequency response of the second amplifying circuit 320. In addition, a response function 530 corresponds to the frequency response of the equalizer 300. From formula (5), the pole 512 and zero 514 of the first amplifying circuit 310 can be derived as follows:

$$\begin{matrix}pole 512 = - \frac{1 + gm1r1}{r1C} & ( 6 ) \\ zero 514 = - \frac{1}{r1C} & ( 7 )\end{matrix}$$

Since the gain of the equalizer 300 is the sum of the first gain A1 and the second gain A2, the location of the pole 532 of the response function 530 of the equalizer 300 is the same with the pole 512 of the response function 510 of the first amplifying circuit 310. However, the location of the zero 534 of the equalizer 300 depends on the gain A2 of the second amplifying circuit 320. When the equalizer 300 increases the gain A2 of the second amplifying circuit 320, the zero 534 shifts to the right. When the equalizer 300 decreases the gain A2 of the second amplifying circuit 320, the zero 534 shifts to the left.

In the equalizer 300, the gain A2 of the second amplifying circuit 320 can be adjusted by changing the resistance of the resistor 340 or the conductance gm2 between the MOS 326 and MOS 328. In practice, adjusting the equivalent current source 322 or 324 can change the conductance gm2.

From formula (6), it is known that adjusting the resistance of the resistor 340 or the conductance gm2 does not change the location of the pole 512 of the first amplifying circuit 310, so the location of the pole 532 of the equalizer 300 is not affected. Accordingly, the flexibility to adjust the effective bandwidth of the equalizer 300 is greatly improved.

Additionally, as is well known in the art, the longer the channel 302 is, the severer the channel attenuation and ISI problem of the received signal Vin are. Therefore, in practical applications, the equalizer architecture of the present invention can further adaptively adjust the gain or frequency response characteristic of the second amplifying circuit 320 according to the practical situation of the channel 302. For example, the resistor 340 can be implemented with an adjustable resistor. A control circuit can be configured in a signal receiver to detect the channel response of the channel 302. The resistance of the resistor 340 is adjusted according to the detection result to change the gain of the second amplifying circuit 320 and the location of the zero 534 of the equalizer 300 is therefore adjusted. In one embodiment, the control circuit can be implemented with a digital signal processor within the signal receiver, so that the performance of the equalizer 300 of the present invention can be further improved.

Those skilled in the art will readily observe that numerous modifications and alterations of the device and method may be made while retaining the teachings of the invention. Accordingly, the above disclosure should be construed as limited only by the metes and bounds of the appended claims.

1. An equalizer having an input end and an output end comprising:
a first circuit, coupled between the input end and the output end, corresponding to a first gain; and
a second circuit, coupled between the input end and the output end, corresponding to a second gain;
wherein a frequency response of the equalizer corresponds to the first gain and the second gain.

2. The equalizer of claim 1, wherein a gain of the equalizer is the sum of the first gain and the second gain.

3. The equalizer of claim 1, wherein a pole of the frequency response corresponds to the first gain.

4. The equalizer of claim 1, wherein the first circuit comprises a capacitor for adjusting the frequency response of the equalizer.

5. The equalizer of claim 1, wherein a zero of the frequency response corresponds to the second gain.

6. The equalizer of claim 5, wherein the second circuit comprises a resistor for adjusting the zero of the frequency response of the equalizer.

7. The equalizer of claim 1, wherein the second circuit comprises a first current source and a second current source, the frequency response of the equalizer is adjusted by changing a current of the first and the second current sources.

8. The equalizer of claim 1, wherein the first circuit is a differentiator and the second circuit is an attenuator.

9. The equalizer of claim 1, wherein the bandwidth of the frequency response of the equalizer is adjusted by changing at least one of the first and second gains.

10. A signal receiver comprising:
an equalizer having an input end and an output end, comprising:
a first circuit, coupled between the input end and the output end, corresponding to a first gain; and
a second circuit, coupled between the input end and the output end, corresponding to a second gain; and
a control circuit coupled to the equalizer, the control circuit utilized to generate a control signal according to a channel response to adjust a frequency response of the equalizer.

11. The signal receiver of claim 10, wherein a pole of the frequency response corresponds to the first gain and a zero of the frequency response corresponds to the second gain.

12. The signal receiver of claim 11, wherein the bandwidth of the frequency response of the equalizer is adjusted by changing at least one of the first and second gains.

13. The signal receiver of claim 10, wherein the control signal is employed to change at least one of the first gain and the second gain in order to adjust the frequency response of the equalizer.

14. The signal receiver of claim 10, wherein the control circuit is a digital signal processor (DSP).

15. The signal receiver of claim 10, further comprising:
a clock-data recovery circuit coupled between the control circuit and the equalizer for processing an output signal of the equalizer.

16. A signal equalizing method comprising:
receiving a signal; and
compensating the received signal according to a gain of an equalizer;
wherein the gain of the equalizer corresponds to a first gain and a second gain, and a frequency response of the gain comprises a pole corresponding to the first gain and a zero corresponding to the second gain.

17. The signal equalizing method of claim 16, further comprising:
adjusting at least one of the first and second gains according to a channel response of the received signal.

18. The signal equalizing method of claim 16, further comprising:
determining a channel response of the received signal; and
adjusting at least one of the first and second gains according to the channel response.
